(19) United States
(12) Patent Application Publication
(10) Pub. No.: US 2010/0133541 A1
(43) Pub. Date: Jun. 3, 2010

(54) THIN FILM TRANSISTOR ARRAY SUBSTRATE, ITS MANUFACTURING METHOD, AND LIQUID CRYSTAL DISPLAY DEVICE

(75) Inventors: Yusuke UCHIDA, Koshi-shi (JP); Koji ODA, Chiyoda-ku (JP); Naoki NAKAGAWA, Chiyoda-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/628,516

(22) Filed: Dec. 1, 2009

(30) Foreign Application Priority Data
Dec. 2, 2008 (JP) 2008-307396

(51) Int. Cl. H01L 33/00; H01L 29/786; H01L 21/336

(52) U.S. Cl. 257/59; 257/57; 438/158; 257/E33.004; 257/E29.291; 257/E21.414

(57) ABSTRACT

In accordance with an exemplary aspect of the present invention, a thin film transistor array substrate includes a transparent insulating substrate, and a thin film transistor for pixel switching and a thin film transistor for a drive circuit formed on the transparent insulating substrate, wherein the thin film transistor for a drive circuit includes an amorphous silicon film formed on the transparent insulating film, a microcrystalline silicon film formed on the amorphous silicon film, a first source electrode and a first drain electrode formed on the microcrystalline silicon film, the first source electrode and the first drain electrode being opposed with a first channel area interposed therebetween, a protective insulating film that covers the first source electrode and the first drain electrode, and an upper gate electrode formed so as to be opposed to the first channel area with the protective insulating film interposed therebetween.

### BACKGROUND OF THE INVENTION

1. Field of the Invention

The present invention relates to a thin film transistor array substrate, its manufacturing method, and a liquid crystal display device.

2. Description of Related Art

Liquid crystal display (LCD) devices, which are a type of flat panels, have merits such as low power consumption, and compact and light-weight, so that they have been widely used as monitors for personal computers, mobile information terminal devices, car navigation systems, and the likes. Further, in recent years, they are also used as television monitors, and beginning to take the place of traditional cathode-ray tubes. Furthermore, organic electro-luminescence (EL) display devices, which are a self-luminous type and superior to liquid crystal display devices in terms of viewing angle, contrast, high-speed response to moving images, and the like, are also beginning to be used as the next generation flat panels.

As for thin film transistors (TFTs) used in such display devices, a metal oxide semiconductor (MOS) structure using a semiconductor film has been used in many cases. TFTs are categorized into several types including a back channel etching type (inversely staggered type) and a top gate type. In many cases, amorphous silicon films are used as the semiconductor films.

In TFTs using amorphous silicon films as semiconductor films, localized level density in the amorphous silicon films increases by electron infusion from the amorphous silicon films to the gate insulating films and trapping. Therefore, they have a drawback that the threshold voltage is shifted. Further, in order to compensate this drawback, an amount of the shift in threshold voltage is estimated in advance and taken into account in their circuit design. However, although TFTs using amorphous silicon films can be used as pixel switches, they cannot be used in gate driver circuits requiring high mobility due to their low mobility and occurrences of the shift. Therefore, there has been a problem that integrated circuits (ICs) for gate derivers need to be externally installed, and thus increasing the size of the frame areas of the display devices.

To solve this problem, it is necessary to form the gate driver circuit with TFTs. As a result, crystalline semiconductor films (microcrystalline semiconductor films and polycrystalline silicon films) have been used as semiconductor films (for example, see Japanese Unexamined Patent Application Publication Nos. 2000-231118 and 7-131030). Since crystalline semiconductor films have a lower localized level density in comparison to amorphous silicon films, they are advantageous in that a shift in threshold voltage hardly occurs, and even if it occurs, the amount of the shift is small. On the other hand, among the crystalline semiconductor films, polycrystalline silicon films involve a crystallization process using an excimer laser or the like, and thus making the manufacturing process complicated and thereby making upsizing and cost reduction very difficult. Therefore, microcrystalline semiconductor films, which can be easily obtained by using only a film-forming device and are superior in terms of productivity, are beginning to attract attention.

However, as well known in the field of solar cells and the like, in the microcrystalline semiconductor film formation, an amorphous incubation layer is formed at an early stage of the film formation. That is, if a microcrystalline semiconductor film is formed as a semiconductor film in a bottom gate type TFT, an incubation layer is formed at an early stage of the film formation. It should be noted that a portion where the incubation layer is formed corresponds to the channel portion on the interface with the gate insulating film, and this portion is the area that could affect the characteristics of the TFT more than any other area does. Therefore, such TFTs cannot be used in liquid crystal display devices. Further, if TFTs using microcrystalline semiconductor films are formed, it is very difficult to remove these incubation layers or transform them into micro crystals after the film formation.

The present invention has been made in view of these problems, and an exemplary object thereof is to provide a thin film transistor array substrate in which the drive circuit is composed of thin film transistors and which is superior in terms of productivity.

### SUMMARY OF THE INVENTION

In accordance with an exemplary aspect of the present invention, a thin film transistor array substrate includes:

a transparent insulating substrate; and

a thin film transistor for pixel switching and a thin film transistor for a drive circuit formed on the transparent insulating substrate,

wherein the thin film transistor for a drive circuit includes:

an amorphous silicon film formed on the transparent insulating film;

a microcrystalline silicon film formed on the amorphous silicon film;

a first source electrode and a first drain electrode formed on the microcrystalline silicon film, the first source electrode and the first drain electrode being opposed with a first channel area interposed therebetween;

a protective insulating film that covers the first source electrode and the first drain electrode; and

an upper gate electrode formed so as to be opposed to the first channel area with the protective insulating film interposed therebetween.

In accordance with another exemplary aspect of the present invention, a method of manufacturing a thin film transistor array substrate that includes a thin film transistor for pixel switching and a thin film transistor for a drive circuit includes:

forming a lower gate electrode on a transparent insulating substrate;

forming a gate insulating film covering the lower gate electrode;

forming an amorphous silicon film on the gate insulating film;

forming a microcrystalline silicon film on the amorphous silicon film;

forming a source electrode and a drain electrode on the microcrystalline silicon film;

forming a protective insulating film covering the source electrode and the drain electrode; and

forming an upper gate electrode on the protective insulating film.

In accordance with an exemplary aspect, the present invention can provide a thin film transistor array substrate in which the drive circuit is composed of thin film transistors and which is superior in terms of productivity.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plane view of a liquid crystal display device in accordance with a first exemplary embodiment of the present invention;

FIG. 2A is a plane view of a TFT of the display section of a liquid crystal display device in accordance with the first exemplary embodiment of the present invention;

FIG. 2B is a cross section taken along the line IIB-IIB of FIG. 2A;

FIG. 3A is a plane view of a TFT of the drive circuit section of a liquid crystal display device in accordance with the first exemplary embodiment of the present invention;

FIG. 3B is a cross section taken along the line IIIB-IIIB of FIG. 3A;

FIG. 4A is a cross section illustrating a manufacturing process of a liquid crystal display device in accordance with the first exemplary embodiment of the present invention;

FIG. 4B is a cross section illustrating a manufacturing process of a liquid crystal display device in accordance with the first exemplary embodiment of the present invention;

FIG. 4C is a cross section illustrating a manufacturing process of a liquid crystal display device in accordance with the first exemplary embodiment of the present invention;

FIG. 4D is a cross section illustrating a manufacturing process of a liquid crystal display device in accordance with the first exemplary embodiment of the present invention;

FIG. 4E is a cross section illustrating a manufacturing process of a liquid crystal display device in accordance with the first exemplary embodiment of the present invention;

FIG. 4F is a cross section illustrating a manufacturing process of a liquid crystal display device in accordance with the first exemplary embodiment of the present invention; and

FIG. 5 is a cross section of a TFT of the drive circuit section of a liquid crystal display device in accordance with the second exemplary embodiment of the present invention.

### DESCRIPTION OF THE EXEMPLARY EMBODIMENTS

Exemplary embodiments of liquid crystal display devices in accordance with exemplary aspects of the present invention are explained hereinafter. However, the present invention is not limited to the exemplary embodiments described below. Further, the following description and the drawings may be partially omitted or simplified as appropriate for clarifying the explanation.

### First Exemplary Embodiment

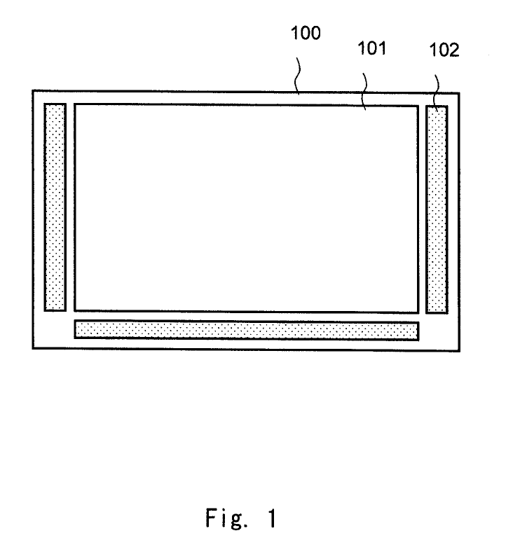

A structure of a liquid crystal display device in accordance with a first exemplary embodiment of the present invention is explained hereinafter with reference to FIGS. 1, 2A, 2B, 3A and 3B. FIG. 1 is a plane view of a liquid crystal display device in accordance with a first exemplary embodiment of the present invention. As shown in FIG. 1, a liquid crystal display device 100 in accordance with this exemplary embodiment includes a display section 101 and a drive circuit section 102.

The display section 101 occupies most of the liquid crystal display device 100, and is composed of a huge number of pixels. Further, each pixel includes a thin film transistor (TFT). That is, the liquid crystal display device 100 is an active matrix type liquid crystal display device.

A drive circuit section 102 is formed in the periphery of the display section 101. In a liquid crystal display device 100 in accordance with an exemplary aspect of the present invention, a drive circuit formed in the drive circuit section 102 is not an externally installed IC chip, but is composed of TFTs that can be formed simultaneously with the TFTs of the display section 101.

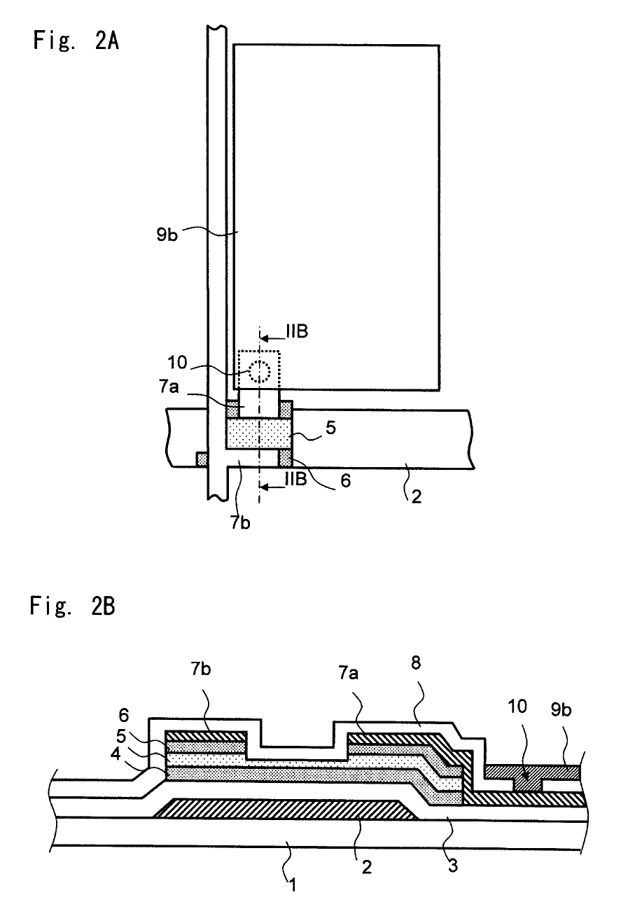

FIG. 2A is a plane view of a display section 101 of a liquid crystal display device 100 in accordance with a first exemplary embodiment of the present invention. FIG. 2B is a cross section taken along the line of FIG. 2A. As shown in FIGS. 2A and 2B, the liquid crystal display device 100 includes, in the display section 101, a transparent insulating substrate 1, gate electrodes/lines 2, a gate insulating film 3, an amorphous silicon film 4, a microcrystalline silicon film 5, an ohmic contact film 6, drain electrodes 7a, source electrodes 7b, a protective film 8, pixel electrodes 9b, and contact holes 10. Note that the illustration of the transparent insulating substrate 1, the gate insulating film 3, and the protective film 8 are omitted in FIG. 2A.

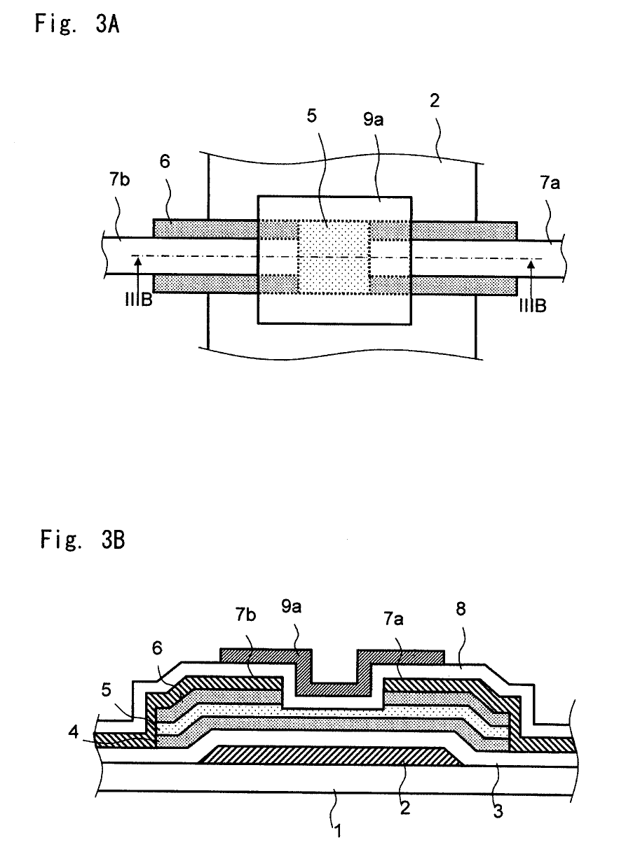

Meanwhile, FIG. 3A is a plane view of a drive circuit section 102 of a liquid crystal display device 100 in accordance with the first exemplary embodiment of the present invention. FIG. 3B is a cross section taken along the line IIIB-IIIB of FIG. 3A. As shown in FIGS. 3A and 3B, the liquid crystal display device 100 includes, in the drive circuit section 102, a transparent insulating substrate 1, gate electrodes/lines 2, a gate insulating film 3, an amorphous silicon film 4, a microcrystalline silicon film 5, an ohmic contact film 6, drain electrodes 7a, source electrodes 7b, a protective film 8, and upper gate electrodes 9a. Note that the illustration of the transparent insulating substrate 1, the gate insulating film 3, and the protective film 8 are omitted in FIG. 3A.

Firstly, common components to the display section 101 and the drive circuit section 102 are explained hereinafter. A glass substrate or other transparent insulating substrates composed of a quartz glass or the like can be used as the transparent insulating substrate 1.

The gate electrodes/lines 2 are formed on the transparent insulating substrate 1. A metal film containing Al, Mo, Cr, Ta, Ti, W, Cu, or the like as the main ingredient can be used as the gate electrode/line 2.

The gate insulating film 3 is formed so as to cover the gate electrodes/lines 2 on the transparent insulating substrate 1. A silicon nitride film (SiNx), a silicon oxide film (SiOx), or a silicon oxide nitride film (SiOxNy), or a laminated film thereof can be used as the gate insulating film 3.

The amorphous silicon film 4 is formed on the gate insulating film 3 so as to be opposed to the gate electrode/line 2. That is, the gate insulating film 3 is located so as to be sandwiched between the gate electrode/line 2 and the amorphous silicon film 4. Further, the microcrystalline silicon film 5 is formed on this amorphous silicon film 4.

The ohmic contact film 6 is formed on the microcrystalline silicon film 5. An n-type a-Si (amorphous silicon) film that is obtained by doping a-Si with a very small amount of P can be used as the ohmic contact film 6. In the channel portion of the TFT, the ohmic contact film 6 is removed on the microcrystalline silicon film 5. That is, the ohmic contact film 6 is formed in two divided regions, i.e., the source side region and drain side region, on one microcrystalline silicon film 5.

The drain electrode 7a and the source electrode 7b are formed on the ohmic contact film 6, and each of them is connected to the microcrystalline silicon film 5 through the ohmic contact film 6. The drain electrode 7a and the source electrode 7b are formed from the one and same metal film. A metal film containing Al, Mo, Cr, Ta, Ti, W, Cu, or the like as the main ingredient can be used as this metal film. The protective film 8 is formed on the drain electrode 7a and the source electrode 7b. Similar material to that for the gate insulating film 3 can be used for the protective film 8.

Next, a structure unique to FIGS. 2A and 2B is explained hereinafter. As shown in FIGS. 2A and 2B, the pixel electrode 9b is formed on the protective film 8 in the display section 101. The pixel electrode 9b is electrically connected to the drain electrode 7a through a contact hole 10 formed in the protective film 8. A transparent conductive film composed of material typified by ITO can be used as the pixel electrode 9b. TFTs formed in the display section 101 are driven by a voltage applied to the gate electrodes/lines 2 by using the amorphous silicon film 4 as a channel.

Next, a structure unique to FIGS. 3A and 3B is explained hereinafter. As shown in FIGS. 3A and 3B, the upper gate electrode 9a is formed on the protective film 8 in the drive circuit section 102. The upper gate electrode 9a is electrically connected to the drain electrode 7a through a contact hole 10 formed in the protective film 8. The upper gate electrode 9a is composed of, for example, the same transparent conductive film as the pixel electrode 9b.

TFTs formed in the drive circuit section 102 are also driven by a voltage applied to the gate electrodes/lines 2 by using the amorphous silicon film 4 as a channel. However, the TFTs formed in the drive circuit section 102 are also driven by a voltage applied to the upper gate electrodes 9a by using the microcrystalline silicon film 5 as a channel. By using the microcrystalline silicon film 5 as a channel, they can be used as a drive circuit.

Note that the TFTs may be driven only by a voltage applied to the upper gate electrodes 9a by using the microcrystalline silicon film 5 as a channel. Therefore, the gate electrodes/lines 2 are not indispensable in the drive circuit section 102.

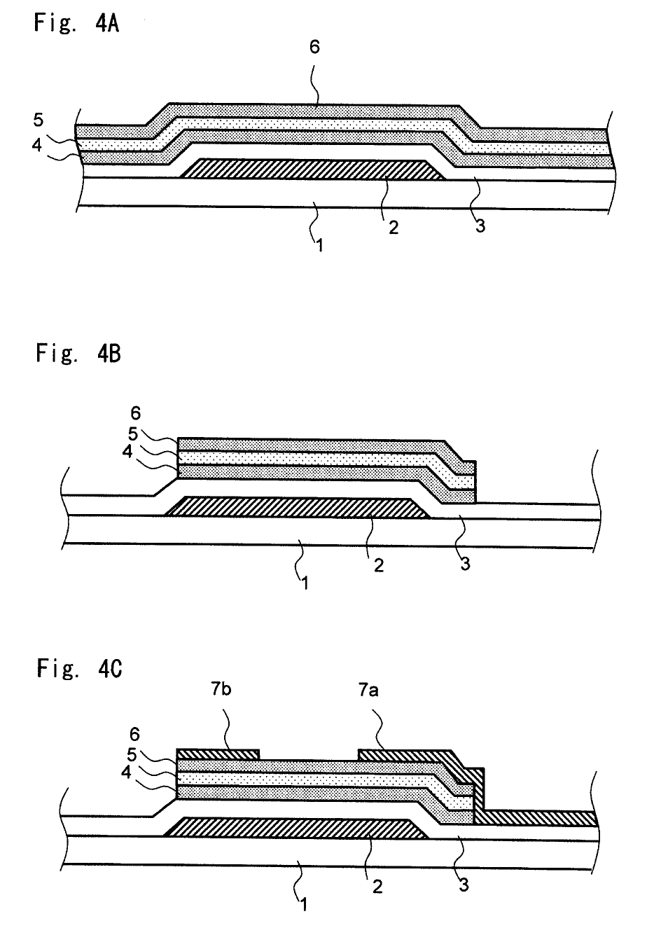

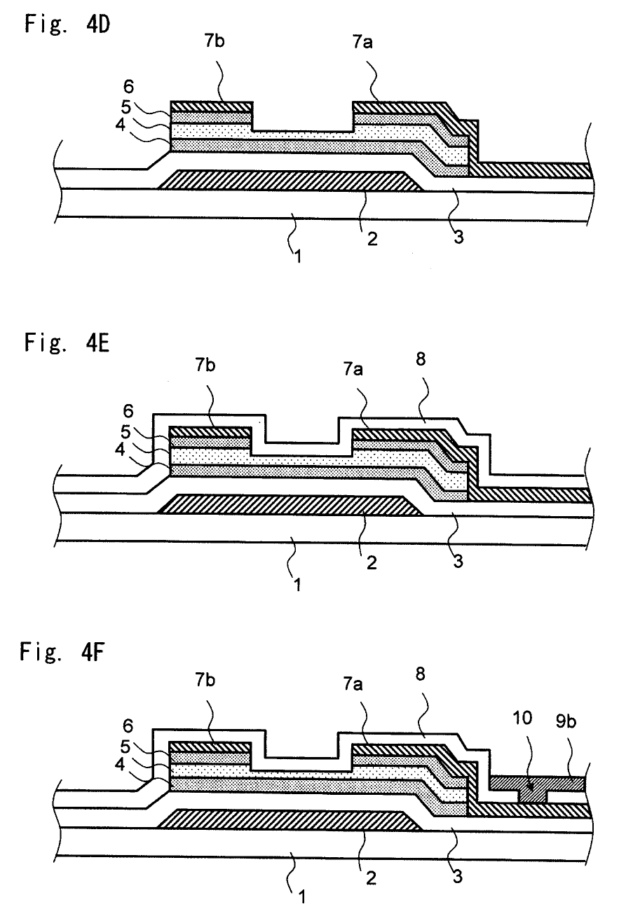

Next, a manufacturing method of a liquid crystal display device in accordance with a first exemplary embodiment of the present invention is explained hereinafter with reference to FIGS. 4A to 4F. Note that an example explained below is merely a typical example, and needless to say, other manufacturing methods can be also adopted as long as they are consistent with the spirit of the present invention.

Firstly, as shown in FIG. 4A, a gate electrode/line 2 is formed on the transparent insulating substrate 1. Specifically, a first metal film that is used to form the gate electrode/line 2 is first formed on the transparent insulating substrate 1 having a cleaned surface by sputtering, vacuum deposition, or a similar method. As a preferable embodiment, a Cr film of 400 nm in thickness is formed by sputtering.

Then, patterning is performed on the first metal film by a first photo-lithography process to form the gate electrode/line 2. The photo-lithography process is performed in the following manner. After the transparent insulating substrate 1 on which the first metal film was formed is cleaned, a photosensitive resist is applied to/dried on the substrate. Next, it is exposed to light through a mask pattern having a predetermined pattern formed thereon and then developed, so that the resist on which the mask pattern is transferred is formed over the substrate by using a photomechanical technique or the like. After this photosensitive resist is cured by heating, etching is performed to remove the photosensitive resist.

The first metal film can be etched by using an etching solution. In the case of the Cr film, a ceric ammonium nitrate solution, for example, may be used as an etching solution. Further, it is preferable to perform the etching of this first metal film in such a manner that the pattern edge has a tapered shape because, by doing so, it can improve the prevention of short-circuit at steps with other lines. Note that the term “tapered shape” means that a pattern edge is etched so that it becomes a trapezoid in cross section.

Next, thin films that are used to form a gate insulating film 3 composed of SiNx, SiOx, SiOxNy, or the like, an amorphous silicon (a-Si) film 4, a microcrystalline silicon film 5, and an ohmic contact film 6 composed of n-type a-Si are formed by a plasma chemical vapor deposition (CVD) method. As a preferable embodiment, a SiNx film having a thickness of 40 to 60 nm, an a-Si film having a thickness of 10 to 100 nm, a microcrystalline silicon film having a thickness of 50 to 150 nm, and an n-type a-Si film having a thickness of 30 to 80 nm are continuously formed. FIG. 4A shows this state.

These gate insulating film 3, amorphous silicon film 4, microcrystalline silicon film 5, and ohmic contact film 6 are preferably formed within the same device or the same chamber in a continuous manner. In this way, it is possible to prevent contaminants existing in the atmosphere such as boron from being taken into these films.

Next, as shown in FIG. 4B, a resist pattern is formed in an area where a TFT is to be formed by a second photo-lithography process. Then, the amorphous silicon film 4, the microcrystalline silicon film 5, and the ohmic contact film 6 are patterned into island shapes by, for example, a dry-etching method using a CF4 gas. After that, the resist is removed.

Next, as shown in FIG. 4C, a second metal film that is used to form the source electrode 7b and the drain electrode 7a is formed by sputtering or a similar method. After that, a resist pattern is formed in areas where the source electrode 7b and the drain electrode 7a are to be formed by a third photo-lithography process. As a preferable embodiment, a Cr film of 300 nm in thickness is formed by sputtering. A wet-etching is used as the etching method for the second metal film. In the case where the second metal film is composed of Cr, a ceric ammonium nitrate solution, for example, may be used as an etching solution. After that, the resist is removed.

Next, as shown in FIG. 4D, the entire ohmic contact film 6 and a part of the microcrystalline silicon film 5 located in the channel region of the TFT are removed. In this way, the microcrystalline silicon film 5 is exposed in the channel portion of the TFT. The ohmic contact film 6 and the microcrystalline silicon film 5 are removed by, for example, a dry-etching method using a CF4 gas.

Next, as shown in FIG. 4E, a film that is used to form the protective film 8 composed of SiNx, SiOx, SiOxNy, or the like is formed by a plasma CVD method. As a preferable embodiment, an SiNx film having a thickness of 10 to 40 nm is formed.

Next, as shown in FIG. 4F, the protective film 8 is formed from this film by a fourth photo-lithography process. An exposure is performed uniformly by using a shield mask (not shown) having openings in places corresponding to contact holes 10. After the above exposure process, it is developed by using a developing fluid. After that, an opening is formed in an area corresponding to the contact hole 10 through an etching process to expose the drain electrode 7a. For example, the SiNx film can be removed by a dry-etching method using a CF4 gas or a mixed gas of SF6 and O2.

Then, a transparent conductive film that is used to form the pixel electrode 9b and the upper gate electrode 9a is formed by a sputtering method, a vacuum deposition method, a coating application method, or the like. After that, in the display section 101, the pixel electrode 9b is formed from the transparent conductive film by a fifth photo-lithography process. At the same time, the upper gate electrode 9a is formed in the drive circuit section 102. Note that if the transparent conductive film is composed of, for example, ITO, an oxalic acid based etching solution may be used. Needless to say, the pixel electrode 9b and the upper gate electrode 9a may be formed from separate conductive films. However, by forming them simultaneously from the single conductive film, the productivity is improved.

A TFT array substrate manufactured in this manner is stuck to an opposed substrate having a color filter and opposed electrodes (not shown) with a spacer interposed therebetween as a pair of substrates, and liquid crystal is injected into a gap therebetween. By installing a liquid crystal panel in which this liquid crystal layer is sandwiched in a back-light unit, the manufacturing of the liquid crystal display device has been completed.

As has been described above, since a liquid crystal display device in accordance with this exemplary embodiment uses a microcrystalline film for the semiconductor layer, it does not require a crystallization process using an excimer laser or the like. That is, it can be easily obtained by using only a film-forming device, and is superior in terms of productivity.

### Second Exemplary Embodiment

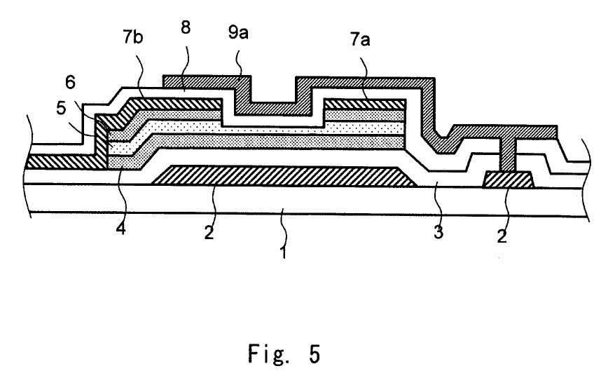

FIG. 5 is a cross section of a TFT of a drive circuit section 102 of a liquid crystal display device in accordance with a second exemplary embodiment of the present invention. It is different from the first exemplary embodiment in that the upper gate electrode 9a is connected to a gate electrode/line 2 through a contact hole pierced through the protective film 8 and the gate insulating film 3. In the first exemplary embodiment, wiring to connect the upper gate electrode 9a with the gate terminal is required. In contrast to that, this second exemplary embodiment has an advantage that since it is already connected to a gate electrode/line 2 that is provided in a lower layer to drive a TFT of the display section 120, additional wiring to connect the upper gate electrode 9a with the gate terminal is unnecessary.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor array substrate comprising:
a transparent insulating substrate; and
a thin film transistor for pixel switching and a thin film transistor for a drive circuit formed on the transparent insulating substrate,
wherein the thin film transistor for a drive circuit comprises:
an amorphous silicon film formed above the transparent insulating film;
a microcrystalline silicon film formed above the amorphous silicon film;
a first source electrode and a first drain electrode formed above the microcrystalline silicon film, the first source electrode and the first drain electrode being opposed with a first channel area interposed therebetween;
a protective insulating film that covers the first source electrode and the first drain electrode; and
an upper gate electrode formed so as to be opposed to the first channel area with the protective insulating film interposed therebetween.

2. The thin film transistor array substrate according claim 1, wherein the thin film transistor for pixel switching comprises:
a lower gate electrode formed above the transparent insulating substrate;
a gate insulating film that covers the lower gate electrode;
the amorphous crystalline silicon film and the microcrystalline silicon film formed so as to be opposed to the lower gate electrode with the gate insulating film interposed therebetween; and
a second source electrode and a second drain electrode formed above the microcrystalline silicon film, the second source electrode and the second drain electrode being opposed with a second channel area interposed therebetween.

3. The thin film transistor array substrate according claim 2, wherein the thin film transistor for a drive circuit comprises the lower gate electrode and the gate insulating film below the first channel area.

4. The thin film transistor array substrate according claim 3, wherein the upper gate electrode is connected to the lower gate electrode through a contact hole piercing through the gate insulating film and the protective insulating film.

5. The thin film transistor array substrate according to claim 1, wherein the upper gate electrode is composed of a same transparent conductive film as a pixel electrode connected to the thin film transistor for pixel switching.

6. The thin film transistor array substrate according to claim 1, wherein the amorphous crystalline silicon film and the microcrystalline silicon film are continuously formed within a same chamber.

7. A liquid crystal display device comprising a thin film transistor array substrate according to claim 1.

8. A method of manufacturing a thin film transistor array substrate, the thin film transistor array substrate comprising a thin film transistor for pixel switching and a thin film transistor for a drive circuit, the method comprising:
forming a lower gate electrode above a transparent insulating substrate;
forming a gate insulating film covering the lower gate electrode;
forming an amorphous silicon film above the gate insulating film;
forming a microcrystalline silicon film above the amorphous silicon film;
forming a source electrode and a drain electrode above the microcrystalline silicon film;
forming a protective insulating film covering the source electrode and the drain electrode; and
forming an upper gate electrode above the protective insulating film.

9. The method of manufacturing a thin film transistor array substrate according to claim 8, wherein, in the forming the upper gate electrode, a pixel electrode connected to the thin film transistor for pixel switching is formed from a same transparent conductive film as the upper gate electrode.

10. The method of manufacturing a thin film transistor array substrate according to claim 8, wherein the forming the amorphous silicon film and the forming the microcrystalline silicon film are continuously performed within a same chamber.
